(19) United States
(12) Patent Application Publication
(10) Pub. No.: US 2011/0199748 A1
(43) Pub. Date: Aug. 18, 2011

(54) SEMICONDUCTOR STORAGE DEVICE AND ELECTRONIC DEVICE

(75) Inventors: Shigeru Kagawa, Kanagawa (JP); Yoshiharu Matsuda, Kanagawa (JP)

(73) Assignee: Kabushiki Kaisha Toshiba, Tokyo (JP)

(21) Appl. No.: 12/976,800

(22) Filed: Dec. 22, 2010

(30) Foreign Application Priority Data
Feb. 17, 2010 (JP) 2010-032950

(51) Int. Cl. H05K 7/14

(52) U.S. Cl. 361/796

(57) ABSTRACT

According to one embodiment, a semiconductor storage device includes a housing, a plurality of circuit boards, and a partition wall. The circuit boards are stacked, spaced apart from one another, and mounted with semiconductor devices including a plurality of nonvolatile semiconductor memories. The partition wall is located between the circuit boards.

### CROSS-REFERENCE TO RELATED APPLICATIONS

This application is based upon and claims the benefit of priority from Japanese Patent Application No. 2010-032950, filed Feb. 17, 2010, the entire contents of which are incorporated herein by reference.

### FIELD

Embodiments described herein relate generally to a semiconductor storage device and an electronic device.

### BACKGROUND

There are semiconductor storage devices provided with a plurality of nonvolatile semiconductor memories mounted on circuit boards such as a solid state drive (SSD) (see, for example, Japanese Patent Application Publication (KOKAI) No. 2009-289278).

Such a semiconductor storage device is required to have an increased storage capacity.

To increase the storage capacity, if the circuit boards having nonvolatile semiconductor memories mounted thereon are stacked one on top of another with a space therebetween, a heat-generating semiconductor device faces another semiconductor device. This may be undesirable in view of heat dissipation.

Further, the nonvolatile semiconductor memories mounted on the circuit boards increase the weight. As a result, the circuit boards are likely to be severely warped due to a shock. This reduces the mounting reliability of components on the circuit boards.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of a semiconductor storage device according to a first embodiment;

FIG. 2 is an exemplary perspective view of the semiconductor storage device viewed at a different angle in the first embodiment;

FIG. 3 is an exemplary schematic cross-sectional view of the semiconductor storage device in the first embodiment;

FIG. 4 is an exemplary exploded perspective view of the semiconductor storage device in the first embodiment;

FIG. 5 is an exemplary exploded perspective view of a base, a first circuit board, and an intermediate member of the semiconductor storage device in the first embodiment;

FIG. 6 is an exemplary perspective view of the base of the semiconductor storage device in the first embodiment;

FIG. 7 is an exemplary exploded perspective view of the first circuit board, the intermediate member, and a second circuit board of the semiconductor storage device in the first embodiment;

FIG. 8 is an exemplary exploded perspective view of the intermediate member, the second circuit board, and a cover of the semiconductor storage device in the first embodiment;

FIG. 9 is an exemplary schematic cross-sectional view of a semiconductor storage device according to a first modification of the first embodiment;

FIG. 10 is an exemplary schematic cross-sectional view of a semiconductor storage device according to a second modification of the first embodiment;

FIG. 11 is an exemplary schematic cross-sectional view of a semiconductor storage device according to a third modification of the first embodiment;

FIG. 12 is an exemplary perspective view of an electronic device according to a second embodiment; and

FIG. 13 is an exemplary perspective view of an electronic device according to a third embodiment.

### DETAILED DESCRIPTION

Various embodiments will be described hereinafter with reference to the accompanying drawings. In general, according to one embodiment, a semiconductor storage device comprises a housing, a plurality of circuit boards, and a partition wall. The circuit boards are configured to be stacked, spaced apart from one another, and mounted with semiconductor devices including a plurality of nonvolatile semiconductor memories. The partition wall are located between the circuit boards.

According to another embodiment, an electronic device comprises a semiconductor storage device. The semiconductor storage device comprises a housing, a plurality of circuit boards, and a partition wall. The circuit boards are configured to be stacked, spaced apart from one another, and mounted with semiconductor devices including a plurality of nonvolatile semiconductor memories. The partition wall are located between the circuit boards.

According to still another embodiment, an electronic device comprises a housing, a plurality of circuit boards, and a partition wall. The circuit boards are configured to be stacked, spaced apart from one another, and mounted with semiconductor devices including a plurality of nonvolatile semiconductor memories. The partition wall are located between the circuit boards.

A description will now be given of a semiconductor storage device 1 according to a first embodiment. Hereinafter, for the sake of convenience of description, the short-side direction of the rectangular top or bottom surface of the semiconductor storage device 1 will be referred to as “X direction”, the longitudinal direction will be referred to as “Y direction”, and the thickness direction (the direction in which circuit boards are stacked) will be referred to as “Z direction”.

The semiconductor storage device 1 of the first embodiment is, for example, a solid state drive (SSD) that is used as being mounted on an electronic device (not illustrated) such as a personal computer, a server, a storage box, or the like. The semiconductor storage device 1 has a flat rectangular parallelepiped shape, and is rectangular in a plan view (i.e., viewed in the Z direction). The semiconductor storage device 1 comprises a housing 2 having as the outer wall a bottom wall 2a, a top wall 2b, and a side wall 2c. Hereinafter, while the outer wall of the housing 2 will be referred to as the bottom wall 2a, the top wall 2b, and the side wall 2c for the sake of convenience, this does not limit the posture of the semiconductor storage device 1 being placed. As illustrated in FIG. 2, part of the housing 2 (in the first embodiment, part of the side wall 2c and the bottom wall 2a) is cut out to expose a connector 3 for external connection.

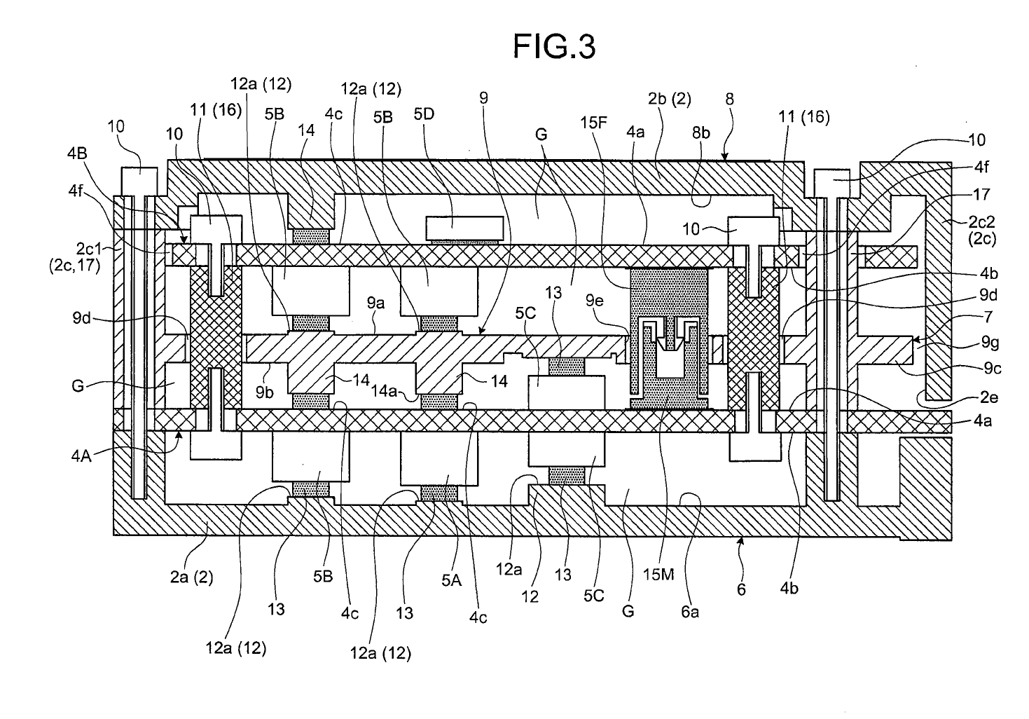

As illustrated in FIG. 3, the housing 2 houses a plurality of circuit boards 4A and 4B (in the first embodiment, two circuit boards) which are stacked with a space between them. The circuit boards 4A and 4B each have a plurality of semiconductor devices mounted thereon. In the first embodiment, the semiconductor storage device 1 is provided with, as the semiconductor devices, a system-on-chip (SoC) device 5A, a NAND flash memory (hereinafter, “NAND”) 5B, a double data-rate random access memory (DDR SDRAM) (hereinafter, “DDR”) 5C, a capacitor 5D, and the like. The SoC 5A is a chip including integration of a central processing unit (CPU), a controller, and the like. The SoC 5A controls data read/write operation with respect to the NAND 5B and the DDR 5C. The SoC 5A also controls data exchange with, for example, a host controller of the electronic device where the semiconductor storage device 1 is mounted according to the serial advanced technology attachment (SATA) standard or the like via the connector 3. The NAND 5B is a nonvolatile semiconductor memory. The capacitor 5D supplements the power supply from the electronic device. All the semiconductor devices generate heat. In the first embodiment, the SoC 5A generates the largest amount of heat.

The first and the second circuit boards 4A and 4B may be, for example, printed circuit boards (PCBs). The semiconductor devices (The SoC 5A, the NAND 5B, the DDR 5C, the capacitor 5D) are mounted on at least one of an upper surface 4a and a lower surface 4b of the first and the second circuit boards 4A and 4B (in the first embodiment, on both the surfaces) by, for example, surface mounting. While the surfaces of the first and the second circuit boards 4A and 4B will be refereed to as the upper surface 4a and the lower surface 4b for the sake of convenience, this does not limit the posture of the first and the second circuit boards 4A and 4B being placed.

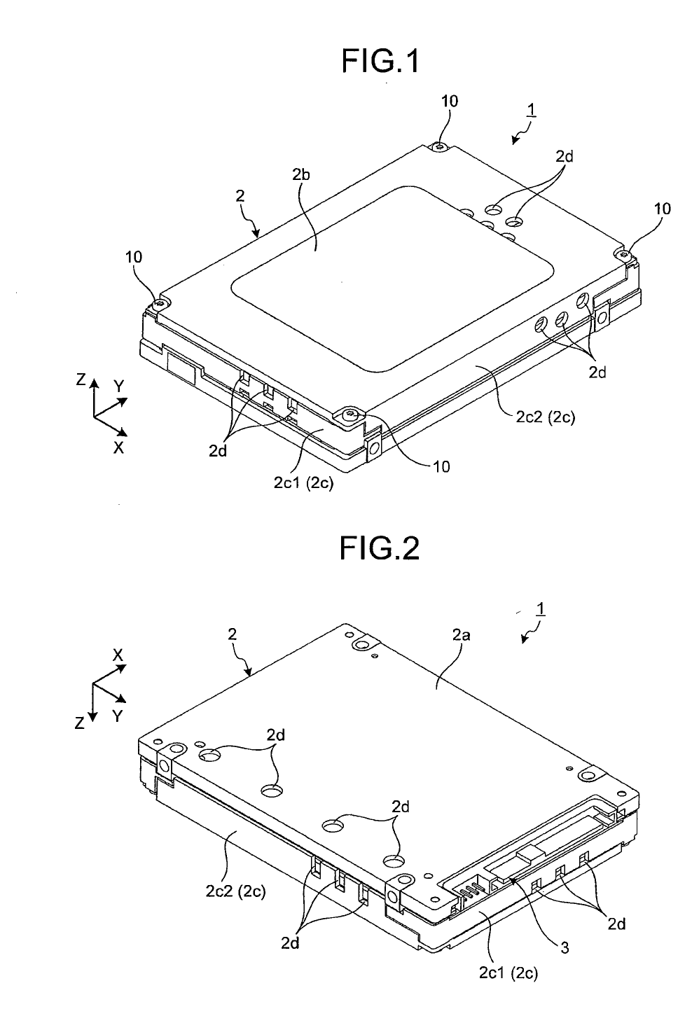

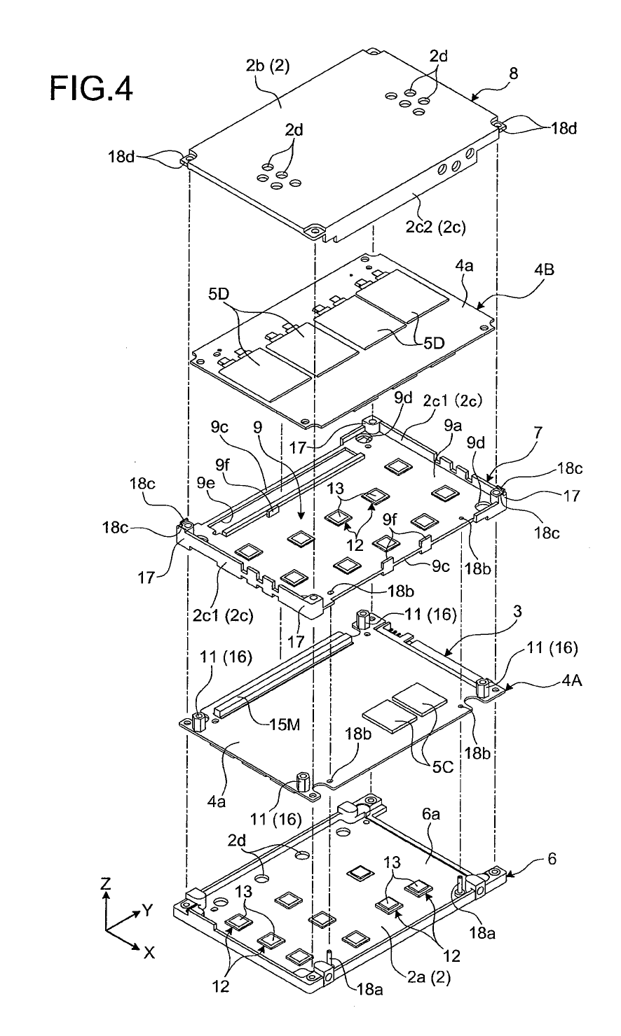

As illustrated in FIG. 4, the semiconductor storage device 1 comprises a base 6, the first circuit board 4A, an intermediate member 7, the second circuit board 4B, and a cover 8. The base 6 mainly forms the bottom wall 2a of the housing 2. The cover 8 mainly forms the top wall 2b of the housing 2 and part of the side wall 2c. The intermediate member 7 mainly forms part of the side wall 2c and a partition wall 9 between the first and the second circuit boards 4A and 4B. In the first embodiment, the base 6, the first circuit board 4A, the intermediate member 7, the second circuit board 4B, and the cover 8 are integrated by fixing members such as a screw 10 and a stud 11 (see FIGS. 1 and 3).

A plurality of pins 18a are provided on an upper surface 6a of the base 6 such that the pins 18a extend toward the cover 8. The circuit board 4A and the intermediate member 7 are provided with through holes 18b that the pins 18a pass through. In the first embodiment, the pins 18a and the through holes 18b position the base 6, the circuit board 4A, and the intermediate member 7 in the X and Y directions. Ribs 18c are provided to opposite corners of the intermediate member 7 such that the ribs 18c extend toward the cover 8. The cover 8 is provided with notches 18d in which the ribs 18c are fitted, respectively. In the first embodiment, the ribs 18c and the notches 18d position the intermediate member 7 and the cover 8 in the Y direction.

In the first embodiment, the base 6 constituting the housing 2 and the partition wall 9, the intermediate member 7, and the cover 8 are each made of a material having good thermal conductivity (metal material such as, for example, aluminum alloy, stainless steel, copper alloy, etc.). With this, heat generated by the semiconductor devices as heat generating elements (the SoC 5A, the NAND 5B, the DDR 5C, and the capacitor 5D) can be easily discharged out of the semiconductor storage device 1 via the housing 2 and the partition wall 9. This helps keep the temperature inside the housing 2 from rising. As described above, preferably, the base 6, the intermediate member 7, and the cover 8 are each made of a material having good thermal conductivity (high thermal conductivity).

Preferably, a film (not illustrated) made of a material having high heat dissipation properties is formed on the surface of the housing 2, the base 6 constituting the partition wall 9, the intermediate member 7, the cover 8, and the like. Specifically, such a film may be formed by the application of a paint containing a filler having good heat dissipation properties (for example, ceramic particles for insulating material, and metal particles and carbon fiber for non-insulating material). With this, heat generated by the semiconductor devices as heat generating elements can further be easily discharged out of the semiconductor storage device 1 via the film. This helps keep the temperature inside the housing 2 from rising. The film may be provided by adhering a sheet having high heat dissipation properties.

As illustrated in FIGS. 1, 2, and 4, preferably, a vent hole 2d is formed in the base 6 constituting the housing 2, the cover 8, and the like so that air is exchanged between inside and outside the housing 2. With this, heat generated by the semiconductor devices as heat generating elements can be easily discharged out of the semiconductor storage device 1 with the air passing through the vent hole 2d. This further helps keep the temperature inside the housing 2 from rising. Preferably, the vent hole 2d is formed at a position facing or near a semiconductor device that generates a large amount of heat (for example, the SoC 5A). In addition, the housing 2 may have a convex and concave outer surface with a fin or the like to increase the heat dissipation properties.

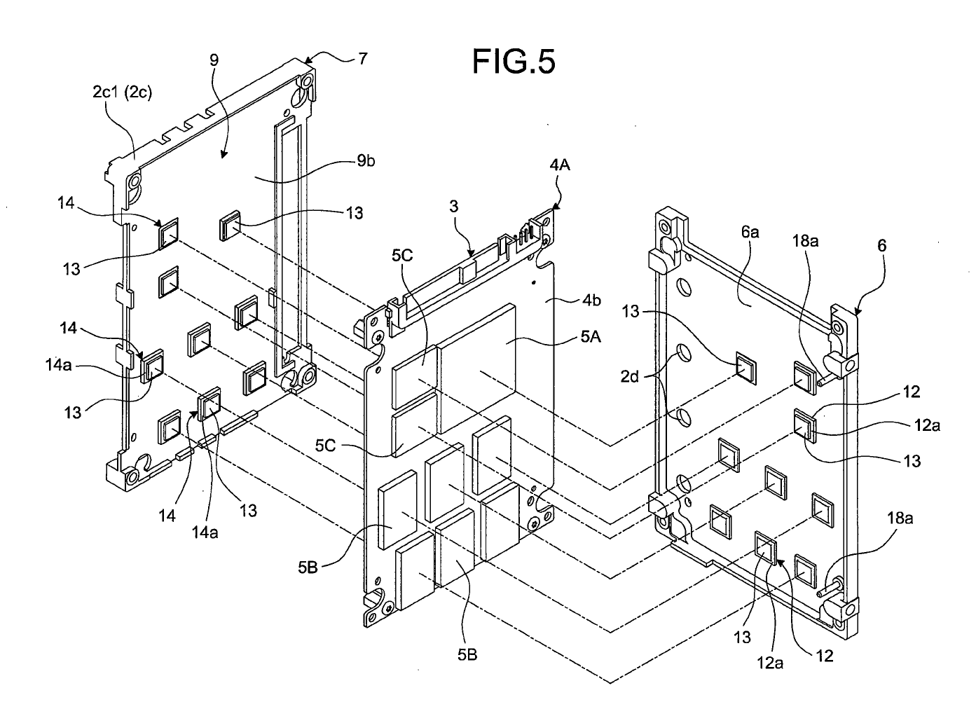

As illustrated in FIG. 5, the semiconductor devices such as the SoC 5A, the NAND 5B, the DDR 5C, and the like are mounted on the lower surface 4b of the first circuit board 4A. As illustrated in FIG. 3, a protrusion 12 facing the center of each semiconductor device (5A, 5B, 5C) is provided on the upper surface 6a of the base 6 that faces the lower surface 4b of the circuit board 4A. The protrusion 12 has a relatively low rectangular column-like shape. A top surface 12a of the protrusion 12 is a flat surface in parallel with the upper surface 6a. Further, as illustrated in FIG. 3, the protrusion 12 has a height that does not interfere with each semiconductor device (5A, 5B, 5C). With this structure, in the first embodiment, the protrusion 12 can be located near a corresponding semiconductor device (5A, 5B, 5C). Accordingly, heat generated by each semiconductor device (5A, 5B, 5C) as a heat generating element can further be easily discharged out of the semiconductor storage device 1 via the protrusion 12 and the base 6. This further helps keep the temperature inside the housing 2 from rising. Moreover, the protrusion 12 provided on part of the upper surface 6a of the base 6 ensures a gap G between the upper surface 6a of the base 6 except the protrusion 12 and the lower surface 4b of the circuit board 4A. This achieves heat dissipation effect by air flows through the gap G. Furthermore, in the first embodiment, since the SoC 5A that generates the largest amount of heat faces the bottom wall 2a (the base 6) as the outer wall of the housing 2, it is possible to increase the heat dissipation to the outside of the semiconductor storage device 1 compared to the case where the SoC 5A faces inside the housing 2.

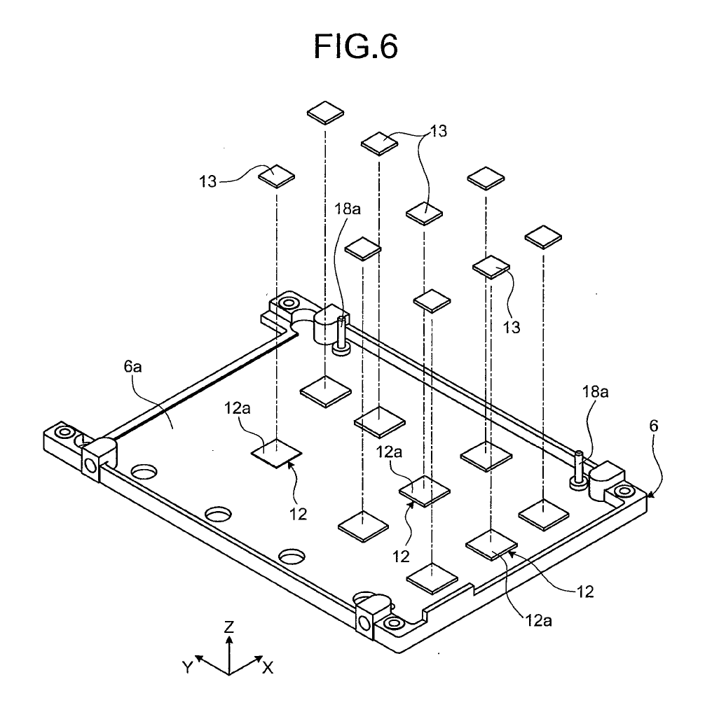

As illustrated in FIGS. 3 and 5, in the first embodiment, an interposition member 13 is arranged between each semiconductor device (5A, 5B, 5C) and the protrusion 12. The interposition member 13 has flexibility (elasticity) and is a flat rectangular sheet. As illustrated in FIG. 6, the interposition member 13 adheres to the top surface 12a of the protrusion 12. As illustrated in FIG. 3, in the state where the circuit board 4A and the base 6 are assembled, the interposition member 13 is in close contact with each semiconductor device (5A, 5B, 5C) and the protrusion 12 in between them. The interposition member 13 is made of a material having good thermal conductivity (for example, acrylic resin, fluororesin, polyamide resin, etc.). With this, heat generated by each semiconductor device (5A, 5B, 5C) as a heat generating element can further be easily discharged out of the semiconductor storage device 1 via the interposition member 13, the protrusion 12, and the base 6. This further helps keep the temperature inside the housing 2 from rising.

As illustrated in FIGS. 3 and 5, a second protrusion 14 is provided on the lower surface of the partition wall 9 of the intermediate member 7 to face the upper surface 4a of the circuit board 4A. The second protrusion 14 is arranged correspondingly to a back area 4c of the upper surface 4a that is on the back side of each semiconductor device (5A, 5B, 5C) mounted on the lower surface 4b. The second protrusion 14 has a relatively low rectangular column-like shape. A top surface 14a of the protrusion 14 is a flat surface in parallel with a lower surface 9b. Further, the protrusion 14 has a height that does not interfere with the circuit board 4A. With this structure, in the first embodiment, the protrusion 14 can be located near the back area 4c of a corresponding semiconductor device (5A, 5B). Accordingly, heat generated by each semiconductor device (5A, 5B) as a heat generating element can further be easily discharged out of the semiconductor storage device 1 via the circuit board 4A, the protrusion 14, and the partition wall 9 (the intermediate member 7). This further helps keep the temperature inside the housing 2 from rising. Moreover, the protrusion 14 provided on part of the lower surface 9b of the partition wall 9 ensures a gap G between the lower surface 9b of the partition wall 9 except the protrusion 14 and the upper surface 4a of the circuit board 4A. This achieves heat dissipation effect by air flows through the gap G.

In the first embodiment, the interposition member 13 is arranged also between the back area 4c and the protrusion 14. The interposition member 13 also adheres to the top surface 14a of the protrusion 14. As illustrated in FIG. 3, in the state where the circuit board 4A and the intermediate member 7 are assembled, the interposition member 13 is in close contact with the back area 4c and the protrusion 14 in between them. With this, heat generated by each semiconductor device (5A, 5B, 5C) as a heat generating element can further be easily discharged out of the semiconductor storage device 1 via the circuit board 4A, the interposition member 13, the protrusion 14, and the partition wall 9 (the intermediate member 7). This further helps keep the temperature inside the housing 2 from rising.

In the first embodiment, the protrusion 12 may serve as a mark to attach the interposition member 13. That is, as illustrated in FIGS. 5 and 6, the protrusions 12 and 14 protrude from the upper surface 6a of the base 6 and the lower surface 9b of the partition wall 9, respectively. Accordingly, an operator or an automatic attachment device with a camera can easily recognize the top surfaces 12a and 14a of the protrusions 12 and 14 as positions to attach the interposition member 13. Preferably, if the surface of the base 6 and the partition wall 9 is painted, paint of a different color from the material of the base 6 and the partition wall 9 (color paint such as black or white paint) is applied, and after that, the top surfaces 12a and 14a of the protrusions 12 and 14 are grinded. This grinding work increases the accuracy of the height of the protrusion 12 protruding from the reference point (reference surface). Moreover, since the paint is grinded from only the top surfaces 12a and 14a, the top surfaces 12a and 14a can be visually distinguished from the upper surface 6a and the lower surface 9b except the protrusions 12 and 14 more clearly.

As illustrated in FIG. 3, part of the semiconductor devices (5A, 5B) mounted on the circuit board 4A is located between the protrusion 12 facing the lower surface 4b as the mounting surface and the protrusion 14 facing the upper surface 4a opposite the mounting surface. That is, heat generated by the semiconductor devices (5A, 5B) is transmitted to the base 6 and the partition wall 9 through the two protrusions 12 and 14. This structure is effective especially for a semiconductor device that generates a large amount of heat (such as the SoC 5A, the NAND 5B, etc.).

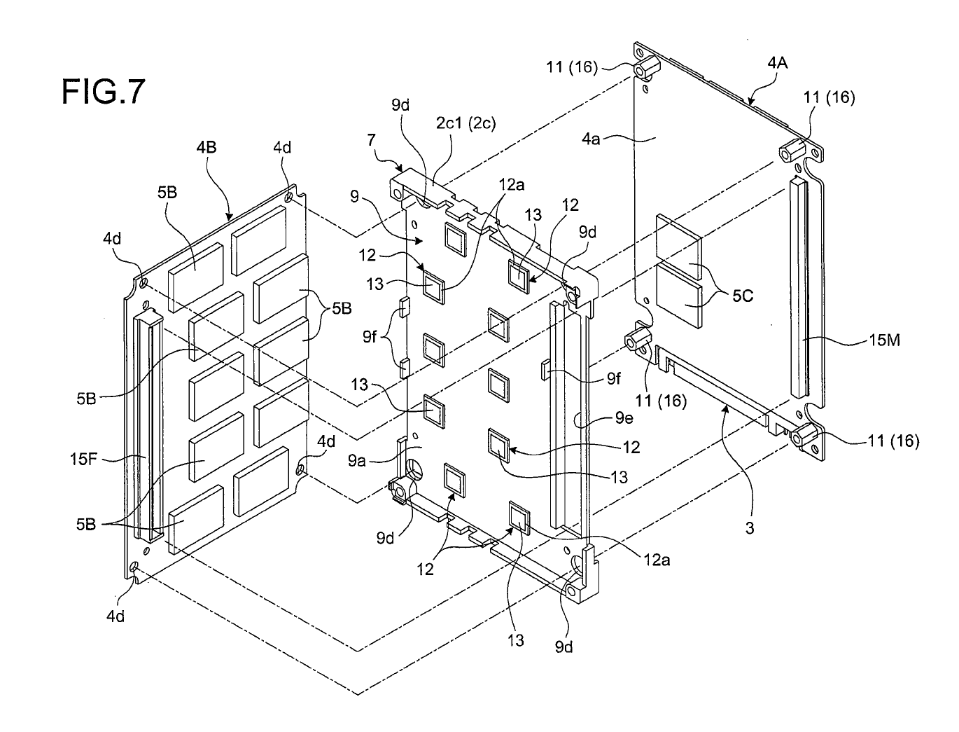

In the first embodiment, as illustrated in FIGS. 3 and 7, the partition wall is located between the circuit boards 4A and 4B. Accordingly, heat generated by a semiconductor device (5A, 5B, 5C, 5D, etc.) mounted on one of the circuit boards 4A and 4B is not transmitted or radiated to the other, which helps keep the temperature inside the housing 2 from rising.

As illustrated in FIGS. 3 and 4, the intermediate member 7 that constitutes the partition wall 9 includes part of the side wall 2c of the housing 2 (in the first embodiment, a side wall 2c1 on both sides in the longitudinal direction, i.e., the Y direction). The side wall 2c1 is connected to the partition wall 9. Accordingly, heat transmitted from a semiconductor device (5A, 5B, 5C, 5D, etc.) to the partition wall 9 is easily discharged out of the semiconductor storage device 1 through the side wall 2c1.

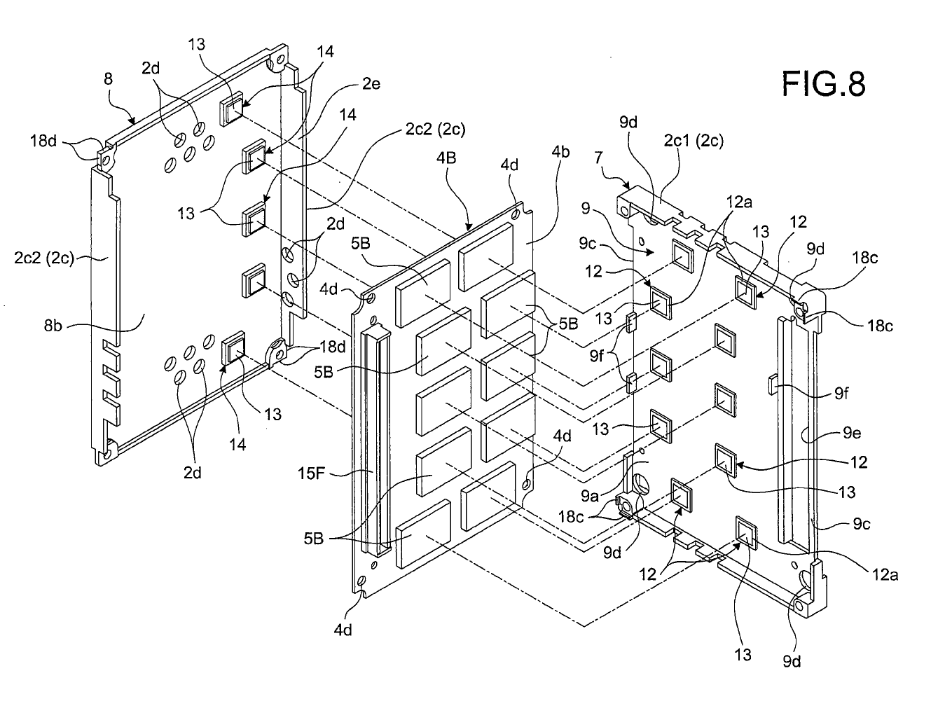

As illustrated in FIGS. 3 and 8, a gap 9g is formed between part of edges of the partition wall 9 (in the first embodiment, an edge 9c on both sides in the short-side direction, i.e., the X direction) and the side wall 2c as the outer wall facing it (in the first embodiment, an inner surface 2e of a side wall 2c2 of the cover 8). This achieves heat dissipation effect by air flows (convective flows) through the gap 9g.

Not only does the partition wall 9 discharge heat generated by a semiconductor device (5A, 5B, 5C, 5D, etc.) mounted on the circuit boards 4A and 4B, but also it prevents the circuit boards 4A and 4B on the both sides from being warped due to a shock. In other words, the partition wall 9 prevents one of the circuit boards 4A and 4B from being warped and coming in contact with the other. At this time, in the first embodiment, the interposition member 13 made of a flexible material serves as a cushion to protect the semiconductor device (5A, 5B, 5C, 5D, etc.).

As illustrated in FIG. 7, in the first embodiment, ribs 9f are provided on an upper surface 9a of the partition wall 9 as the third protrusions facing the lower surface 4b of the circuit board 4B. With this, if the circuit board 4B is warped and bulges toward the partition wall 9 due to the inertia of falling, the ribs 9f support the circuit board 4B and reduce the warping thereof. The ribs 9f are provided on the partition wall 9 to face a semiconductor device (5A, 5B, 5C, 5D, etc.) on the circuit board 4B. Besides, in the first embodiment, the circuit board 4A supports the circuit board 4B at the four corners of the circuit board 4B. Therefore, the circuit board 4B is warped more at the center of the edges. In view of this, the ribs 9f are provided at the center of the edges of the partition wall 9 to correspond to the center of the edges of the circuit board 4B. This effectively reduces the warping of the circuit board 4B. Although not illustrated, the third protrusion may be provided on the lower surface 9b of the partition wall 9 to face the upper surface 4a of the circuit board 4A. The third protrusion may also be provided at a position not interfering with a semiconductor device (5A, 5B, 5C, 5D, etc.) at the center of the partition wall 9, i.e., a position facing an area where no semiconductor device (5A, 5B, 5C, 5D, etc.) is mounted in the centers of the circuit boards 4A and 4B.

As illustrated in FIG. 3, the circuit board 4A is relatively tightly connected to the base 6 and the partition wall 9. The circuit board 4B is electrically connected to the circuit board 4A via connectors 15M and 15F. The connector 15M is surface mounted on the circuit board 4A, while the connector 15F is surface mounted on the circuit board 4B. The connectors 15M and 15F engage with each other. Thus, the circuit boards 4A and 4B are relatively tightly connected via the connectors 15M and 15F. In the first embodiment, the circuit board 4B is connected to the circuit board 4A via an inter-board connector 16, and is not directly connected to the housing 2 (the bottom wall 2a, the top wall 2b, the side wall 2c, etc.) and the partition wall 9. That is, an inter-board-housing connector 17 passes through the circuit board 4B from the front to the back without touching the circuit board 4B (with a space 4f), and connects the circuit board 4A and the base 6 to the cover 8. In this manner, according to the first embodiment, the circuit board 4B is covered with the outer wall of the housing 2, and the circuit board 4B is not directly connected to the housing 2. This prevents forces or moments from acting in different directions between the circuit boards 4A and 4B from the outside through the housing 2 and the connector 3, thereby preventing forces or moments from acting between the connectors 15M and 15F that connects the circuit boards 4A and 4B. Thus, it is possible to prevent failure in the connection of the connectors 15M and 15F. The space 4f between the circuit board 4B and the inter-board-housing connector 17 allows air to flow between the front and back of the circuit board 4B. This achieves heat dissipation effect by air flows through the space 4f.

With respect to the connection between the circuit boards 4A and 4B, as illustrated in FIG. 7, the stud 11 is attached to the upper surface 4a of the circuit board 4A as the inter-board connector 16. Meanwhile, a through hole 9d is formed in the partition wall 9 of the intermediate member 7 to allow the stud 11 to pass through from the front to the back. Correspondingly to the stud 11 passing through the through hole 9d, a through hole 4d is formed in the circuit board 4B that a screw (not illustrated) passes through. The screw passing through the through hole 4d from the upper surface 4a of the circuit board 4B is connected to the stud 11, and thereby the circuit boards 4A and 4B are connected to each other. An elongated rectangular through hole 9e is formed in the partition wall 9 that the connectors 15M and 15F pass through. A predetermined clearance is defined between the through holes 9d and 9e, and the corresponding stud 11 and the connectors 15M and 15F such that the partition wall 9, the stud 11 as the inter-board connector 16, and the connectors 15M and 15F are not in contact with each other. The clearance allows air to flow between the front and back of the partition wall 9. This achieves heat dissipation effect by air flows through the clearance.

In the first embodiment, the connector 3 for external connection is connected to the circuit board 4A relatively tightly connected to the base 6 and reinforced by the base 6. Accordingly, when the connector 3 is connected to or disconnected from the connector (not illustrated) of a corresponding electronic device, the force or moment is prevented from acting on the circuit board 4A as well as a semiconductor device (5A, 5B, 5C, etc.) thereon.

As illustrated in FIG. 8, a semiconductor device such as the NAND 5B is mounted on the lower surface 4b of the second circuit board 4B. As illustrated in FIG. 3, the protrusion 12 facing the center of each semiconductor device (5B) is provided on the upper surface 9a of the partition wall 9 of the intermediate member 7 that faces the lower surface 4b of the circuit board 4B. The protrusion 12 has the same shape, effect, and the like as previously described for the protrusion 12 provided on the lower surface 9b of the partition wall 9. With this structure, in the first embodiment, the protrusion 12 can be located near a corresponding semiconductor device (5B). Accordingly, heat generated by each semiconductor device (5B) as a heat generating element can further be easily discharged out of the semiconductor storage device 1 via the protrusion 12 and the partition wall 9. This further helps keep the temperature inside the housing 2 from rising. Moreover, the protrusion 12 provided on part of the upper surface 9a of the partition wall 9 ensures a gap G between the upper surface 6a of the base 6 except the protrusion 12 and the lower surface 4b of the circuit board 4A. This achieves heat dissipation effect by air flows through the gap G.

The interposition member 13 is attached also to the top surface 12a of the protrusion 12. As illustrated in FIG. 3, in the state where the circuit board 4A and the intermediate member 7 are assembled, the interposition member 13 is in close contact with each semiconductor device (5B) and the corresponding protrusion 12 in between them. With this, heat generated by each semiconductor device (5B) as a heat generating element can further be easily discharged out of the semiconductor storage device 1 via the interposition member 13, the protrusion 12, and the partition wall 9 (the intermediate member 7). This further helps keep the temperature inside the housing 2 from rising.

Besides, the second protrusion 14, which faces the upper surface 4a of the circuit board 4B, is provided on a lower surface 8b of the cover 8. The second protrusion 14 is arranged correspondingly to the back area 4c of the upper surface 4a that is on the back side of each semiconductor device (5B) mounted on the lower surface 4b. The second protrusion 14 has the same shape, effect, and the like as previously described for the second protrusion 14 provided on the lower surface 9b of the partition wall 9. With this structure, in the first embodiment, the second protrusion 14 can be located near the back area 4c of the semiconductor device (5B). Accordingly, heat generated by each semiconductor device (5B) as a heat generating element can further be easily discharged out of the semiconductor storage device 1 via the circuit board 4B, the protrusion 14, and the cover 8. This further helps keep the temperature inside the housing 2 from rising. Moreover, the protrusion 14 provided on part of the lower surface 8b of the cover 8 ensures a gap G between the lower surface 8b of the cover 8 except the protrusion 14 and the upper surface 4a of the circuit board 4B. This achieves heat dissipation effect by air flows through the gap G. The interposition member 13 is attached also to the second protrusion 14 of the cover 8. In the state where the cover 8 and the circuit board 4B are assembled, the interposition member 13 is located between the second protrusion 14 and the back area 4c.

As described above, according to the first embodiment, the semiconductor storage device 1 comprises the plurality of circuit boards 4A and 4B with the partition wall 9 between them. Accordingly, heat generated by a semiconductor device (5A, 5B, 5C, 5D) mounted on one of the circuit boards 4A and 4B is prevented from being transmitted or radiated to the other. Thus, the temperature is prevented from rising at where the circuit boards 4A and 4B faces each other compared to the case of without the partition wall 9. Moreover, the partition wall 9 prevents one of the circuit boards 4A and 4B from interfering with the other when the one is warped.

According to the first embodiment, the partition wall 9 is connected to the housing 2. More specifically, the partition wall 9 is integrated with part of the side wall 2c. Further, the partition wall 9 is connected to the bottom wall 2a and the top wall 2b via the inter-board-housing connector 17. Accordingly, heat generated by a semiconductor device (5A, 5B, 5C, 5D) can be transmitted to the housing 2 and discharged out of the semiconductor storage device 1 from the housing 2. Thus, the temperature is further prevented from rising at where the circuit boards 4A and 4B faces each other.

According to the first embodiment, the partition wall 9 and the housing 2 have the protrusion 12 that faces a semiconductor device (5A, 5B, 5C, 5D). Accordingly, heat generated by the semiconductor device (5A, 5B, 5C, 5D) is easily transmitted to the partition wall 9 and the housing 2 through the protrusion 12. Thus, the temperature is further prevented from rising at where the circuit boards 4A and 4B faces each other.

According to the first embodiment, the partition wall 9 and the housing 2 have the second protrusion 14 that protrudes toward the back area 4c of the circuit boards 4A and 4B on the back side of where a semiconductor device (5A, 5B, 5C, 5D) is mounted. Accordingly, heat generated by the semiconductor device (5A, 5B, 5C, 5D) is easily transmitted to the partition wall 9 and the housing 2 through the second protrusion 14. Thus, the temperature is further prevented from rising at where the circuit boards 4A and 4B faces each other.

According to the first embodiment, the protrusion 12 and the second protrusion 14 are provided correspondingly to at least one semiconductor device (5A, 5B, 5C, 5D). Accordingly, heat generated by the semiconductor device (5A, 5B, 5C, 5D) is easily transmitted to the partition wall 9 and the housing 2 through the protrusions 12 and 14. Thus, the temperature is further prevented from rising at where the circuit boards 4A and 4B faces each other.

According to the first embodiment, the semiconductor storage device 1 comprises the interposition member 13 located between the partition wall 9 and the housing 2 and a semiconductor device (5A, 5B, 5C, 5D). Accordingly, heat generated by the semiconductor device (5A, 5B, 5C, 5D) is efficiently transmitted to the partition wall 9 and the housing 2 through the interposition member 13. Thus, the temperature is further prevented from rising at where the circuit boards 4A and 4B faces each other.

According to the first embodiment, the interposition member 13 is located between the partition wall 9 and the housing 2 and a semiconductor device (5A, 5B, 5C, 5D). Accordingly, the protrusion 12 and the second protrusion 14 each serve as a mark to attach the interposition member 13, which facilitates the attachment of the interposition member 13 and increases the positioning accuracy of the interposition member 13. Moreover, the interposition member 13 can be made thinner by the protrusion of the protrusion 12 and the second protrusion 14. Therefore, if the interposition member 13 is expensive, the manufacturing cost can be reduced.

According to the first embodiment, among the plurality of circuit boards 4A and 4B, the circuit board 4A is connected to the housing 2, while the circuit board 4B is connected to the housing 2 via at least the inter-board connector 16. This prevents forces or moments from acting in different directions between the circuit boards 4A and 4B from the outside through the housing 2 and the connector 3, thereby preventing forces or moments from acting on the connectors 15M and 15F and the circuit boards 4A and 4B.

According to the first embodiment, among the plurality of circuit boards 4A and 4B, the circuit board 4A and the base 6 as part of the housing 2 are connected rigidly, which is desirable to provide the connector 3 for external connection to the circuit board 4A. With this, it is possible to prevent forces or moments from acting on the circuit board 4A and a semiconductor device (5A, 5B, 5C, 5D) through the connector 3.

According to the first embodiment, the SoC 5A as a semiconductor device that generates heat is mounted on the lower surface 4b of the circuit board 4A that faces the housing 2. Accordingly, heat generated by the SoC 5A is easily discharged out of the semiconductor storage device 1 through the outer wall of the housing 2 compared to the case where the SoC 5A is mounted on the upper surface 4a of the circuit board 4A inside the housing 2.

As in the first embodiment, it is preferable to form a film containing a heat dissipating material to coat the surface of at least one of the housing 2 and the partition wall 9. With this, the efficiency of heat transmission to the housing 2 and the partition wall 9 can be increased. Thus, it is possible to improve the performance of discharging heat out of the semiconductor storage device 1.

As in the first embodiment, it is preferable to form the vent hole 2d in the outer wall of the housing 2. This achieves heat dissipation effect by air flows through the vent hole 2d.

As in the first embodiment, it is preferable to form the through hole 9e that the connectors 15M and 15F, which electrically connect the partition wall 9 and the circuit boards 4A and 4B, pass through with a clearance therebetween. This achieves heat dissipation effect by air flows through the clearance.

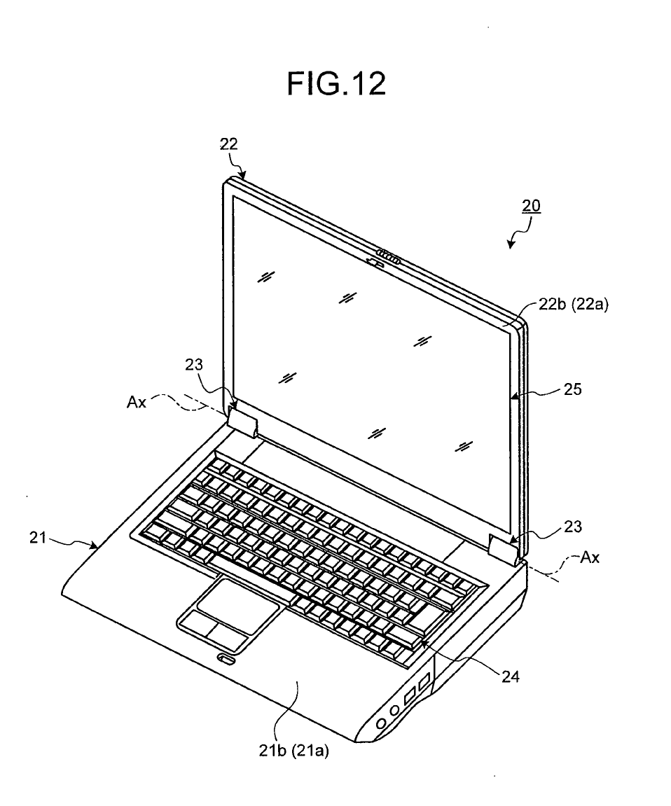

FIG. 12 is a perspective view of an electronic device 20 according to a second embodiment. As illustrated in FIG. 12, the electronic device 20 is, for example, a notebook personal computer. The electronic device 20 comprises a flat rectangular first body 21 and a flat rectangular second body 22. The first body 21 and the second body 22 are connected by a hinge mechanism 23 to be relatively rotatable about a rotation axis Ax between an open position as illustrated in FIG. 12 and a closed position (not illustrated).

The first body 21 is provided with a keyboard 24 as an input device, which are exposed on a front surface 21b as the outer surface of a housing 21a. On the other hand, the second body 22 is provided with a display device 25 such as a liquid crystal display (LCD) panel, which is exposed on a front surface 22b as the outer surface of a housing 22a. When the first body 21 and the second body 22 are in the open position as illustrated in FIG. 12, the keyboard 24, the display device 25, and the like are exposed to allow the user to use them. On the other hand, in the closed position, the front surface 21b closely faces the front surface 22b, and the keyboard 24, the display device 25, and the like are covered between the housings 21a and 22a.

In the second embodiment, the semiconductor storage device 1 exemplified in the first embodiment is attached to the housing 21a of the first body 21. More specifically, a recess (not illustrated) is formed in the back surface of the housing 21a as a container of the semiconductor storage device 1 such that the semiconductor storage device 1 is housed in the recess. Besides, the first body 21 is provided with a connector corresponding to the connector 3 of the semiconductor storage device 1 to face the recess. The connector is connected to the connector 3 of the semiconductor storage device 1. In addition, a cover is attached to the back surface of the housing 21a to cover the recess housing the semiconductor storage device 1.

The semiconductor storage device 1 comprising the housing 2 or constituent elements (i.e., the circuit boards 4A and 4B, the partition wall 9, etc.) of the semiconductor storage device 1 except the housing 2 may be housed in the housing 21a of the electronic device 20. In the latter case, the housing 21a of the electronic device 20 also serves as the housing of the semiconductor storage device 1. The semiconductor storage device 1 may be provided in the housing 22a of the second body 22. Further, a plurality of the semiconductor storage devices 1 may be provided in the housing 21a (or 22a) of the electronic device 20.

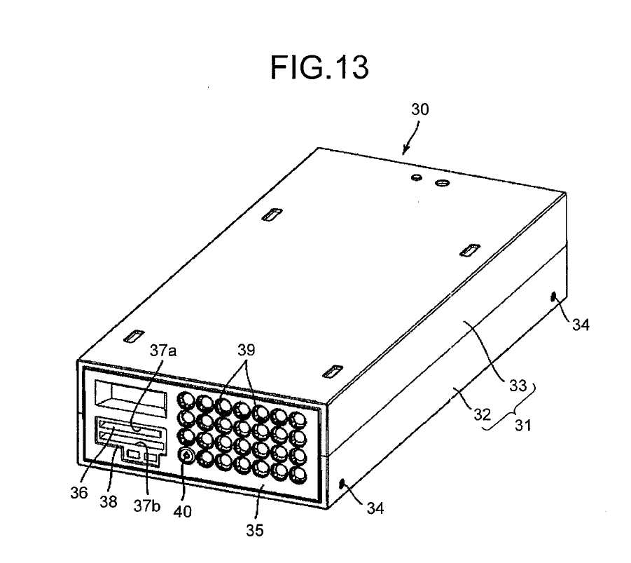

FIG. 13 is a perspective view of an electronic device 30 according to a third embodiment. As illustrated in FIG. 13, the electronic device 30 is, for example, a box-shaped server. The electronic device 30 comprises a rectangular parallelepiped housing 31. The housing 31 comprises a first divisional body 32 and a second divisional body 33. Inside the housing 31, a plate-like or a frame-like framework member (not illustrated) is provided, and the first divisional body 32 is fixed to the framework member with a screw 34 or the like. The second divisional body 33 is removably attached to the first divisional body 32. The operator (user) can remove the second divisional body 33 from the first divisional body 32 to expose the inside of the housing 31, and attach/detach the semiconductor storage device 1 to/from the framework member. A plurality of the semiconductor storage devices 1 may be housed in the housing 31.

The electronic device 30 comprises a plate 35 on one side in the longitudinal direction. The semiconductor storage device 1 also comprises a card holder 36 provided with card slots 37a and 37b. Formed in the plate 35 are a slit 38 corresponding to the card slots 37a and 37b and openings 39 functioning as vent holes. The electronic device 30 is provided with a lock mechanism 40 corresponding to one of the openings 39.

The electronic device 30 may comprise a plurality of the semiconductor storage devices 1 having the housing 2 exemplified in the first embodiment. Besides, constituent elements (i.e., the circuit boards 4A and 4B, the partition wall 9, etc.) of the semiconductor storage device 1 except the housing 2 may be housed in the housing 31 of the electronic device 30. In this case, the housing 31 of the electronic device 30 also serves as the housing of the semiconductor storage device 1.

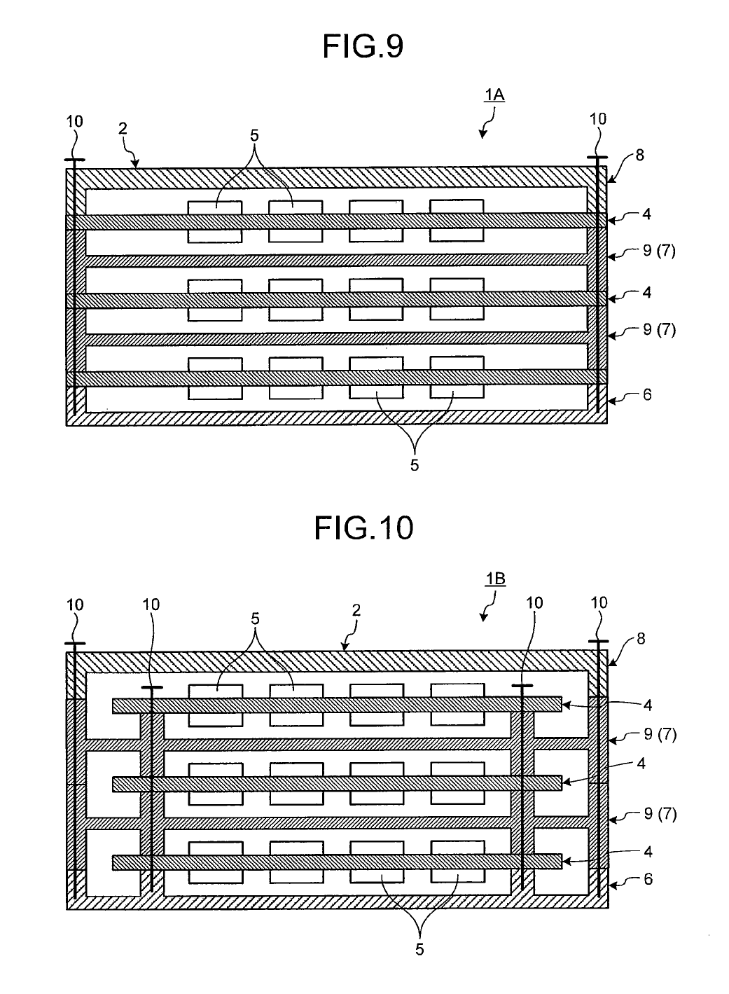

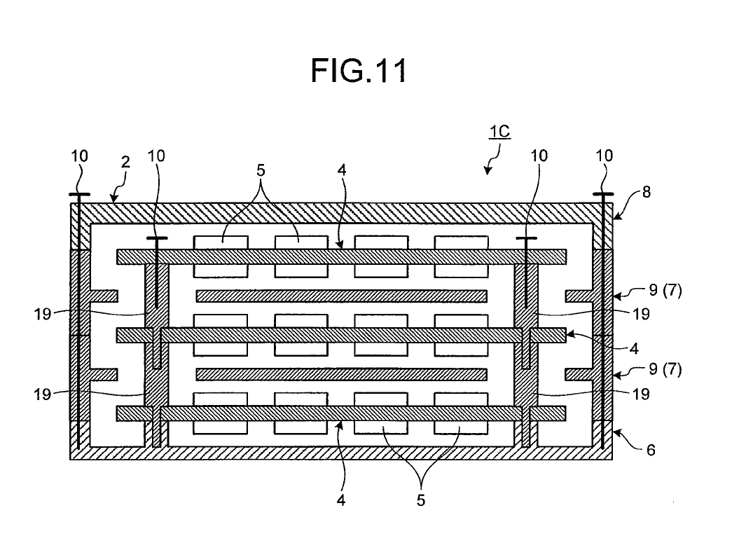

The foregoing embodiments are susceptible to considerable variation in their practice. FIG. 9 is a schematic cross-sectional view of a semiconductor storage device 1A according to a first modification of the first embodiment. As illustrated in FIG. 9, the semiconductor storage device 1A may comprise two or more circuit boards 4 having semiconductor devices 5 mounted thereon. The circuit boards 4 and the partition wall 9 may be fixed to the housing 2. FIG. 10 is a schematic cross-sectional view of a semiconductor storage device 1B according to a second modification of the first embodiment. As illustrated in FIG. 10, in the semiconductor storage device 1B, the circuit boards 4 having the semiconductor devices 5 mounted thereon may be fixed to the partition wall 9. FIG. 11 is a schematic cross-sectional view of a semiconductor storage device 1C according to a third modification of the first embodiment. As illustrated in FIG. 11, in the semiconductor storage device 1C, the circuit boards 4 may be attached to the housing 2 by a combination of a plurality of studs 19 with a bolt.

Although not illustrated, a semiconductor device that generates the largest amount of heat may be mounted on the surface that faces the partition wall of the circuit board. This structure is effective in the case where some problems arise when the outer wall of the housing is heated by the heat generated by the semiconductor device.

The specification (number, location, shape, size, material, etc.) can be changed as required for the circuit board, the housing, the partition wall, the protrusion, the second protrusion, the third protrusion, the interposition member, the inter-board connector, the inter-board-housing connector, the electronic device, and the like. In addition, a through hole may be formed in the partition wall as required.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a housing;
a plurality of circuit boards configured to be stacked, spaced apart from one another, and mounted with semiconductor devices including a plurality of nonvolatile semiconductor memories; and
a partition wall located between the circuit boards.

2. The semiconductor storage device of claim 1, wherein the partition wall is configured to be connected to the housing.

3. The semiconductor storage device of claim 1, wherein the partition wall or the housing comprises a protrusion facing one of the semiconductor devices.

4. The semiconductor storage device of claim 1, wherein the partition wall or the housing comprises a second protrusion protruding toward a back side of an area of each of the circuit boards where the semiconductor devices are mounted.

5. The semiconductor storage device of claim 3, wherein
the partition wall or the housing comprises the protrusion and a second protrusion protruding toward a back side of an area of each of the circuit boards where the semiconductor devices are mounted, and
the protrusion and the second protrusion are configured to correspond to at least one of the semiconductor devices.

6. The semiconductor storage device of claim 1, further comprising an interposition member located between the partition wall or the housing and the semiconductor devices.

7. The semiconductor storage device of claim 5, further comprising an interposition member located between the protrusion or the second protrusion and the semiconductor devices.

8. The semiconductor storage device of claim 1, further comprising an inter-board connector configured to connect the circuit boards, wherein
one of the circuit boards is connected to the housing, and another of the circuit boards is connected to the housing via at least the inter-board connector.

9. The semiconductor storage device of claim 8, wherein the circuit board connected to the housing comprises a connector for external connection.

10. The semiconductor storage device of claim 1, wherein the semiconductor devices that generate heat are mounted on a surface of the circuit boards facing the housing.

11. The semiconductor storage device of claim 1, wherein the partition wall comprises a third protrusion configured to protrude toward an area of each of the circuit boards where none of the semiconductor devices is mounted.

12. The semiconductor storage device of claim 11, wherein the third protrusion is configured to correspond to a center of an edge of the circuit board.

13. An electronic device comprising a semiconductor storage device comprising:
a housing;
a plurality of circuit boards configured to be stacked, spaced apart from one another, and mounted with semiconductor devices including a plurality of nonvolatile semiconductor memories; and
a partition wall located between the circuit boards.

14. An electronic device comprising:
a housing;
a plurality of circuit boards configured to be stacked, spaced apart from one another, and mounted with semiconductor devices including a plurality of nonvolatile semiconductor memories; and
a partition wall located between the circuit boards.
